(19) United States
(12) Patent Application Publication
(10) Pub. No.: US 2007/0090453 A1
(43) Pub. Date: Apr. 26, 2007

(54) NON-VOLATILE MEMORY AND MANUFACTURING METHOD AND OPERATING METHOD THEREOF

(76) Inventors: Yung-Chung Lee, Taipei County (TW); Shi-Shien Chen, Hsinchu City (TW); Hann-Ping Hwang, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/307,804

(22) Filed: Feb. 23, 2006

(30) Foreign Application Priority Data
Oct. 21, 2005 (TW) 94136825

(51) Int. Cl. H01L 29/94

(52) U.S. Cl. 257/330; 257/E27.092

(57) ABSTRACT

A non-volatile memory unit includes a substrate, a conductive layer, a charge storage layer, a first doped regions, two second doped regions, a first bit line and a second bit line. Wherein, there is a trench in the substrate, the conductive layer is disposed in the substrate and filled the trench. The charge storage layer is disposed between the conductive layer and the substrate. The first doped region is disposed in the substrate below the trench, and the second doped regions are disposed in the substrate on the two sides of the trench respectively. Plural control gates are located above the select gates and aligned in parallel and extend in a second direction. The first bit line and the second bit line are disposed on the substrate and electrically connected to the two second doped regions respectively and parallel to each other.

### CROSS-REFERENCE TO RELATED APPLICATION

This application claims the priority benefit of Taiwan application serial no. 94136825, filed on Oct. 21, 2005. All disclosure of the Taiwan application is incorporated herein by reference.

### BACKGROUND OF THE INVENTION

1. Field of Invention

The present invention relates to a semiconductor device, the manufacturing method and the operating method thereof. More particularly, the present invention relates to a non-volatile memory, the manufacturing method and the operating method thereof.

2. Description of Related Art

Because electrically erasable programmable read only memory (EEPROM) of non-volatile memory has the advantages of allowing multiple times of data storing, reading, and erasing, and retaining the stored data even when the power is cut off, EEPROM has been broadly used in personal computers and electronic apparatuses.

A typical EEPROM employs the floating gate and the control gate made of doped polysilicon. When programming the memory, the electrons implanted into the floating gate are uniformly distributed in the whole polysilicon floating gate layer. However, if the tunneling oxide layer under the polysilicon floating gate layer has defects, it can easily cause a leakage current of the device, affecting the reliability of the device.

Therefore, in order to solve the problem of the leakage current in the EEPROM device, a conventional method is to employ a charge storage layer to replace the polysilicon floating gate, and the material of the charge storage layer is, for example, silicon nitride. Generally, a silicon oxide layer is provided on the top and bottom of the silicon nitride charge storage layer respectively to form a stacked gate structure having the laminated silicon oxide/silicon nitride/silicon oxide (ONO) layer. The above stacked gate EEPROM structure is referred as a silicon/silicon oxide/silicon nitride/silicon oxide/silicon (SONOS) memory. When a voltage is applied to the control gate and the source/drain region of the device to program, hot electrons are generated near the drain region in the channel region and implanted into the charge storage layer. Because silicon nitride has the property of capturing electrons, the electrons implanted in the charge storage layer will not uniformly distribute over the whole charge storage layer, but concentrate in local regions of the charge storage layer. Since the electrons implanted into the charge storage layer just concentrate in local regions, it is not so sensitive to the defects of the tunneling oxide layer, and thus lessening the leakage current of the device.

However, a plane SONOS memory having the stacked gate on its substrate surface is unable to be programmed/read at the same time, and the SONOS memory having vertical structure as disclosed in U.S. Pat. No. 6,853578 of Micro Technology also have the same problems.

### SUMMARY OF THE INVENTION

In view of the above, an object of the present invention is to provide a non-volatile memory unit, which allows performing programming/reading/erasing on two memory cells in a memory unit at the same time.

Another object of the present invention is to provide a non-volatile memory array having the self-aligned word line, source line and drain region.

Yet another object of the present invention is to provide a method of manufacturing the non-volatile memory array, which has simplified processes.

Still another object of the present invention is to provide a method of operating the non-volatile memory, which can perform operations to the memory unit more easily.

The present invention provides a non-volatile memory unit, which comprises a substrate, a conductive layer, a charge storage layer, a first doped region, two second doped regions, a first conductive line, and a second conductive line. A trench is formed in the substrate, and the conductive layer is disposed in trench and extending along the trench. The charge storage layer is disposed between the conductive layer and the substrate. The first doped region is disposed in the trench, and the two second doped regions are disposed in the substrate on both sides of the trench respectively. A first conductive line and a second conductive line are disposed on the substrate in parallel, and are electrically connected to one of the two second doped regions respectively. The first conductive line and the second conductive line extend in the direction of intersecting the conductive layer.

According to a preferred embodiment of the present invention, the above non-volatile memory unit further comprises a plurality of conductive plugs disposed on the substrate, for connecting a second doped region on one side of the trench to the first conductive line, and a second doped region on the other side of the trench to the second conductive line respectively.

According to a preferred embodiment of the present invention, in the above non-volatile memory unit, the material of the conductive layer is, for example, doped polysilicon.

According to a preferred embodiment of the present invention, in the above non-volatile memory unit, the material of the charge storage layer comprises silicon nitride.

According to a preferred embodiment of the present invention, the above non-volatile memory unit further comprises a first dielectric layer disposed under the charge storage layer.

According to a preferred embodiment of the present invention, in the above non-volatile memory unit, the material of the first dielectric layer comprises silicon oxide.

According to a preferred embodiment of the present invention, the above non-volatile memory unit further comprises a second dielectric layer disposed above the charge storage layer.

According to a preferred embodiment of the present invention, in the above non-volatile memory unit, the material of the second dielectric layer comprises silicon oxide.

According to a preferred embodiment of the present invention, in the above non-volatile memory unit, the material of the conductive plugs comprises polysilicon.

According to a preferred embodiment of the present invention, in the above non-volatile memory unit, the material of the first conductive lines and the second conductive lines comprises the metal tungsten.

The present invention provides a non-volatile memory array, which comprises a substrate, a plurality of memory cell columns, and a plurality of isolation structures. A plurality of trenches is provided in the substrate, wherein the trenches are arranged in parallel, and extend in the row direction. A plurality of isolation structures is disposed in the substrate, for isolating the memory cell columns. The plurality of memory cell columns includes a plurality of memory units. Each of the memory unit comprises a word line, a charge storage layer, a first doped region, a second doped region, a third doped region, a first conductive line, a second conductive line, and a third conductive line. The word line is disposed in one of the trenches and extends in the trench, for connecting the memory units in the same row. The charge storage layer is disposed between the word line and the trench. The first doped region is disposed in the substrate under the corresponding trench, and shared by the memory units in the same row. The second doped region and the third doped region arranged alternatively are disposed in the substrate at both sides of the trench. The first conductive line and the second conductive line are disposed on the substrate in parallel, extend along the column direction, and are electrically connected to one of the second doped region and the third doped region respectively. The third conductive line is disposed on the substrate, for connecting the first doped region. The second doped regions and the third doped regions of the memory units in the same column are arranged alternatively, and one of the second doped regions or the third doped regions is shared by the two adjacent memory units.

According to a preferred embodiment of the present invention, the above non-volatile memory array further comprises a plurality of conductive plugs disposed on the substrate, for connecting the second doped regions to the first conductive lines, and third doped regions to the second conductive lines, and the first doped regions to the third conductive lines respectively.

According to a preferred embodiment of the present invention, in the above non-volatile memory array, the isolation structures comprise shallow trench isolation structures.

According to a preferred embodiment of the present invention, the above non-volatile memory array further comprises a plurality of first dielectric layers disposed between the charge storage layers and the trench surfaces respectively.

According to a preferred embodiment of the present invention, the above non-volatile memory array further comprises a plurality of second dielectric layers disposed between the charge storage layers and the word lines respectively.

The present invention provides a method of manufacturing the non-volatile memory. Firstly, a substrate is provided, in which a plurality of isolation structures is formed in parallel and extends in a first direction. Then, a plurality of trenches is formed in the substrate in parallel and extends in a second direction, where the second direction is intersected with the first direction. Thereafter, a plurality of first doped regions is formed in the substrates under the trenches, and then a plurality of second doped regions and a plurality of third doped regions are formed in the substrates on both sides of the trenches, wherein the second doped regions and the third doped regions are arranged alternatively in the first direction. Next, a plurality of charge storage layers is formed on surfaces of the substrates in the trenches, and a plurality of word lines, filling the trenches, is formed on the substrates. After that, a plurality of first conductive lines and a plurality of second conductive lines are formed on the substrates in parallel, and extend in the first direction, and are electrically connected to the second doped regions and the third doped regions respectively.

According to a preferred embodiment of the present invention, the above method of manufacturing the non-volatile memory further comprises forming a plurality of conductive plugs on the substrate, for connecting the second doped regions to the first conductive lines, and the third doped regions to the second conductive lines respectively.

According to a preferred embodiment of the present invention, in the above method of manufacturing the non-volatile memory, the method for forming the first doped regions, the second doped regions, and the third doped regions comprises ion implantation.

According to a preferred embodiment of the present invention, the above method of manufacturing the non-volatile memory further comprises forming a first dielectric layer between the charge storage layer and the substrate and under each charge storage layer.

According to a preferred embodiment of the present invention, the above method of manufacturing the non-volatile memory further comprises forming a second dielectric layer between the charge storage layer and the word line and above each charge storage layer.

According to a preferred embodiment of the present invention, in the above method of manufacturing the non-volatile memory, the word line is formed by first forming a conductive material layer on the substrate, and filling the trench; then, removing the conductive material layer formed outside the trench.

According to a preferred embodiment of the present invention, in the above method of manufacturing the non-volatile memory, the method for removing the conductive material layer formed outside the trench comprises chemical mechanical polishing.

The present invention provides a method of operating the non-volatile memory, which is suitable for a memory cell array arranged in columns/rows. The method of operating the non-volatile memory comprises the steps as follows.

When programming, a first voltage is applied to the first conductive line corresponding to the selected first memory cell, and a second voltage is applied to the first doped region of the selected first memory cell, and a third voltage is applied to the word line of the selected first memory cell, wherein the first voltage is higher than the second voltage for programming an upper bit of the first memory cell, and the third voltage is higher than the threshold voltage of the memory unit.

The second voltage is applied to the first conductive line corresponding to the selected first memory cell, and the first voltage is applied to the first doped region of the selected first memory cell, and the third voltage is applied to the word line of the selected first memory cell, for programming a bottom bit of the first memory cell.

According to a preferred embodiment of the present invention, the above method of operating the non-volatile memory further comprises the steps as follows.

When programming, a seventh voltage is applied to the second conductive line corresponding to the selected second memory cell, and an eighth voltage is applied to the first doped region of the selected second memory cell, and a ninth voltage is applied to the word line of the selected second memory cell, wherein the seventh voltage is higher than the eighth voltage for programming an upper bit of the second memory cell, and the ninth voltage is higher than the threshold voltage of the memory unit.

The eighth voltage is applied to the second conductive line corresponding to the selected second memory cell, and the seventh voltage is applied to the first doped region of the selected second memory cell, and the ninth voltage is applied to the word line of the selected second memory cell, for programming a bottom bit of the second memory cell.

According to a preferred embodiment of the present invention, the above method of operating the non-volatile memory further comprises the steps as follows.

When reading the upper bit of the second memory cell, a tenth voltage is applied to the second conductive line corresponding to the selected second memory cell, and an eleventh voltage is applied to the first doped region of the selected second memory cell, and a twelfth voltage is applied to the word line of the selected second memory cell, wherein the tenth voltage is lower than the eleventh voltage, the twelfth voltage is higher than the threshold voltage of the second memory cell before it is programmed, and is lower than the threshold voltage of the second memory cell after it is programmed.

When reading the bottom bit of the second memory cell, the eleventh voltage is applied to the second conductive line corresponding to the selected second memory cell, and the tenth voltage is applied to the first doped region of the selected second memory cell, and the twelfth voltage is applied to the word line of the selected second memory cell.

According to a preferred embodiment of the present invention, the above method of operating the non-volatile memory further comprises the steps as follows.

When reading the upper bit of the first memory cell, a fourth voltage is applied to the first conductive line corresponding to the selected first memory cell, and a fifth voltage is applied to the first doped region of the selected first memory cell, and a sixth voltage is applied to the word line of the selected first memory cell, wherein the fourth voltage is lower than the fifth voltage, the sixth voltage is higher than the threshold voltage of the first memory cell before it is programmed, and is lower than the threshold voltage of the first memory cell after it is programmed.

When reading the bottom bit of the first memory cell, the fifth voltage is applied to the first conductive line corresponding to the selected first memory cell, and the fourth voltage is applied to the first doped region of the selected first memory cell, and the sixth voltage is applied to the word line of the selected first memory cell.

According to a preferred embodiment of the present invention, the above method of operating the non-volatile memory comprises applying a thirteenth voltage to the substrate and applying a fourteenth voltage to the word line of the selected memory unit when erasing, wherein the thirteenth voltage is higher than the fourteenth voltage, for performing erasing by the F-N tunneling effect.

The non-volatile memory structure of the present invention has separated bit lines, thus allowing performing the programming/reading/erasing on two memory cells in the same memory unit.

Moreover, the word line, source line and drain region can be formed in a self-aligned way according to the method of manufacturing the non-volatile memory of the present invention, thus simplifying the process efficiently.

On the other hand, the voltages can be applied to the separated bit lines as desired according to the method of operating the non-volatile memory of the present invention, such that it is easier to operate the memory unit.

It is to be understood that both the foregoing general description and the following detailed description are exemplary, and are intended to provide further explanation of the invention as claimed.

### BRIEF DESCRIPTION OF THE DRAWINGS

FIG. 1 A˜FIG. 1D are three-dimensional views of the process steps for the non-volatile memory according to an embodiment of the present invention.

FIG. 2 is a three-dimensional view of the non-volatile memory according to an embodiment of the present invention.

FIG. 3 shows a circuit diagram of the non-volatile memory according to an embodiment of the present invention.

FIG. 4˜FIG. 7 are schematic views of the programming operation of an embodiment of the present invention.

FIG. 8˜FIG. 11 are schematic views of the reading operation of an embodiment of the present invention.

FIG. 12 is a schematic view of the erasing operation of an embodiment of the present invention.

### DESCRIPTION OF EMBODIMENTS

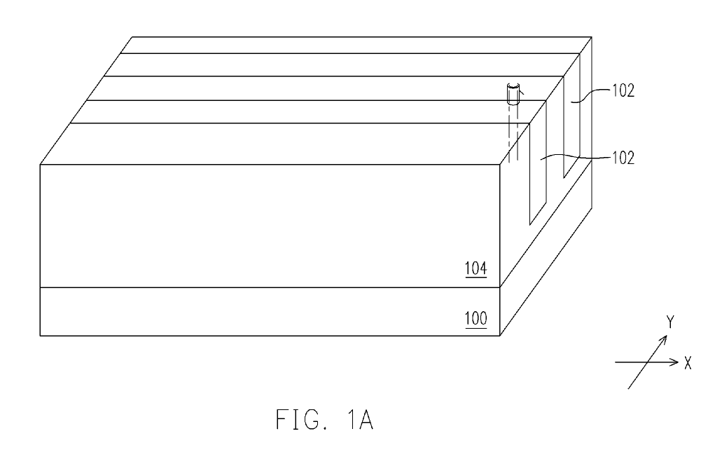

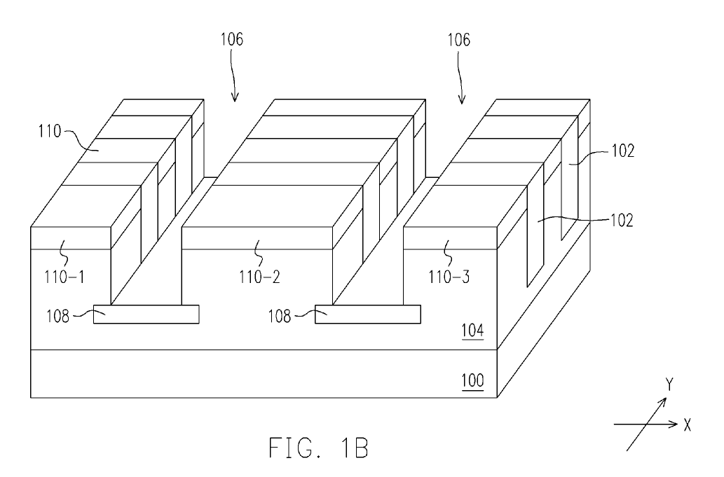

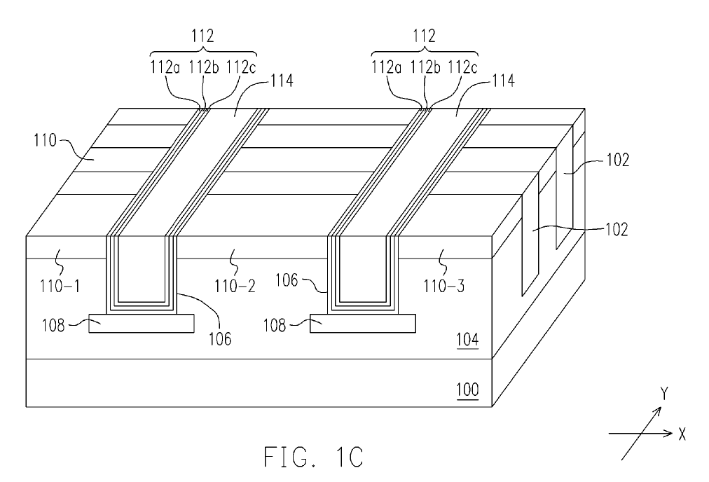

FIG. 1 A˜FIG. 1D are three-dimensional views of the process steps for a non-volatile memory according to an embodiment of the present invention.

Firstly, referring to FIG. 1A, a substrate 100, for example, a silicon substrate, is provided. A plurality of isolation structures 102 is formed in the substrate 100. The isolation structures 102 are, for example, shallow trench isolation structures, and made of, for example, silicon oxide. The isolation structures 102 are arranged in parallel, and extend in X direction of a X-Y plane, wherein the X direction is, for example, the column direction in the memory array, and the Y direction is, for example, the row direction in the memory array. The isolation structure 102 is formed by, for example, forming a pad oxide layer (not shown), a hard mask layer (not shown) and a patterned mask layer (not shown) on the substrate 100 sequentially; performing a dry etching process to the hard mask layer and the pad oxide layer using the patterned mask layer as a mask; removing the patterned mask layer; and then removing a part of the substrate 100 by using the patterned pad oxide layer and the hard mask layer as a mask, to form a plurality of trenches (not shown); thereafter, forming an isolation material layer on the substrates 100 and filling the trench; then performing a chemical mechanical polishing by using the hard mask layer as a polishing stop layer, to remove a part of the isolation material, thereby forming the isolation structures 102. After that, the pad oxide layer and the hard mask layer are removed.

Then, a well region 104, for example, a P-type well region, is formed in the substrate 100. The P-type well region is formed by, for example, ion implantation with boron. Moreover, after forming the well region 104, an annealing process can be further performed to repair the lattice defects of the substrate 100 when performing ion implantation.

Thereafter, referring to FIG. 1B, the trenches 106 are formed in the substrate 100 in parallel, and extend in Y direction. The trenches 106 are formed by, for example, forming a patterned mask layer (not shown) on the substrate 100; performing a dry etching on the substrate 100 using the patterned mask layer as a mask; and then removing the patterned mask layer.

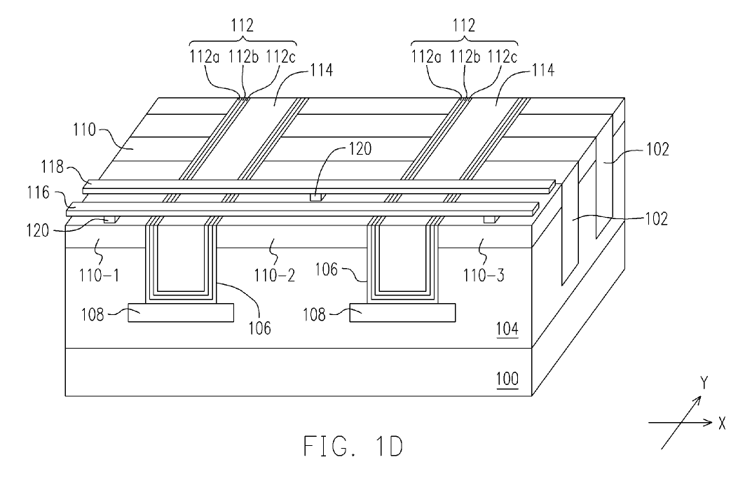

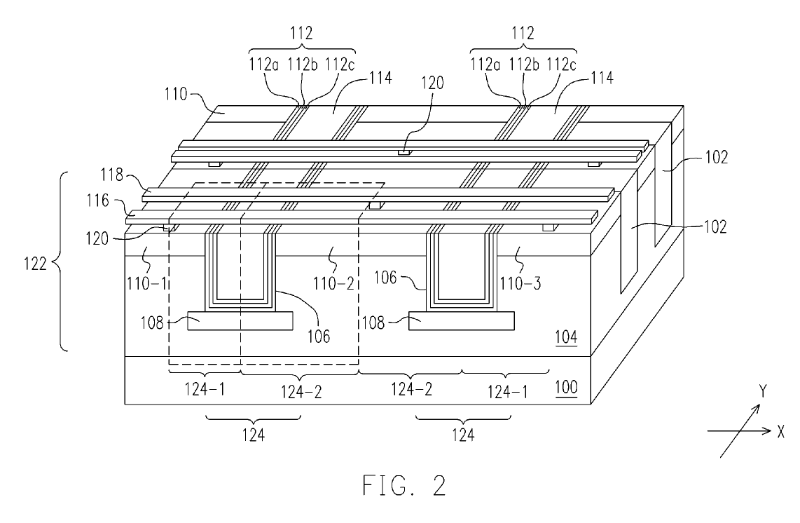

Then, a doping process is performed to the substrate 100, for example, ion implantation with phosphor, to form a doped region 108 in the substrate 100 under the trench 106, and to form a doped region 110 in the substrate 100 on both sides of the trench 106. The doped region 108 and the doped region 110 are, for example, N-type doped regions. The doped region 110 is numbered along the X direction as (2n−1)th (e.g. doped region 110-1 and 110-3 in FIG. 1B) and 2nth (e.g. doped region 110-2 in FIG. 1B), wherein n is an integer larger than 1.

Furthermore, referring to FIG. 1C, a composite layer 112 is formed on the surface of the substrate 100 in the trench 106. The composite layer 112 includes, for example, a dielectric layer 112a, a charge storage layer 112b, and a dielectric layer 112c. The composite layer 112 is formed by, for example, forming the dielectric layer 112a, the charge storage layer 112b, and the dielectric layer 112c on the substrate 100 sequentially. The material of the dielectric layer 112a is, for example, silicon oxide, and is formed by, for example, chemical vapor deposition (CVD) or thermal oxidization. The material of the charge storage layer 112b is, for example, silicon nitride or doped polysilicon, and is formed by, for example, CVD. The material of the dielectric layer 112c is, for example, silicon oxide, and is formed by, for example, CVD.

Then, a word line 114 filling the trench 106 is formed over the substrate 100. The material of the word line 114 is, for example, doped polysilicon. The word line 114 is formed by, for example, forming a doped polysilicon material layer (not shown) on the substrate 100 by CVD with in-situ doping to fill the trench 106. Then, the doped polysilicon material layer outside the trench 106 is removed by, for example, removing the doped polysilicon material layer and the composite layer 112 outside the trench 106 by chemical mechanical polishing by using the substrate 100 as a polishing stop layer.

Then, referring to FIG. 1D, a bit line 116 and a bit line 118 are formed over the substrate 100. The bit line 116 is electrically connected to the (2n−1)th doped region 110 (e.g. the doped region 110-1 and 110-3 in FIG. 1D). The bit line 118 is electrically connected to the 2nth doped region 110 (e.g. the doped region 110-2 in FIG. 1D), and the bit line 116 and the bit line 118 are arranged in parallel and extend in X direction. The bit line 116 and the bit line 118 are electrically connected to the doped region 110. For example, through the conductive plugs 120, the (2n−1)th doped region 110 (e.g. the doped region 110-1 and 110-3 in FIG. 1D) and the bit line 116 are electrically connected and the 2nth doped region 110 (e.g. the doped region 110-2 in FIG. 1D) and the bit line 118 through the conductive plugs 120 are electrically connected.

Moreover, before forming the bit line 116, the bit line 118 and the conductive plug 120, a dielectric layer (not shown) can be formed to cover the substrate 100, and the bit line 116, the bit line 118 and the conductive plug 120 are formed, for example, in the dielectric layer. The material of the bit lines 116/118 is, for example, the metal tungsten, and the material of the conductive plug 120 is, for example, polysilicon.

In another embodiment, the bit line 116, the bit line 118 and the conductive plug 120 are formed by, for example, firstly forming a conductive plug 120, and then forming the bit lines 116/118. The conductive plug 122 is formed by, for example, forming a patterned mask layer over the substrate 100, and then performing a dry etching process to the dielectric layer over the substrate by using the patterned mask layer as a mask, so as to define a conductive plug opening (not shown). Thereafter, the patterned mask layer is removed. And then, a conductive material layer (not shown) filling the conductive plug opening is formed by deposition; and back etching is performed to form the conductive plug 120. The bit lines 116/118 are formed by, for example, forming another conductive material layer (not shown) and a patterned mask layer (not shown) on the dielectric layer sequentially; then performing dry etching to the conductive material layer by using the patterned mask layer as a mask. Then, the patterned mask layer is removed.

In the above method of manufacturing the non-volatile memory, since the doped region 108, word line 114 and bit lines 116,118 can be formed in a self-aligned way, the manufacture processes can be simplified and the production yield is improved. Moreover, the formed non-volatile memory has a vertical memory cell structure, can store two-bits per cell.

The non-volatile memory structure of the present invention is described below.

FIG. 2 is a three-dimensional view of the non-volatile memory according to an embodiment of the present invention.

Referring to FIG. 2, the non-volatile memory array in the present invention comprises a substrate 100, at least an isolation structure 102 and at least a memory cell column 122. The substrate 100 is formed with a well region 104, and the trenches 106 are arranged in parallel and extend in Y direction. The well region 104 is, for example, a P-type well region.

The isolation structures 102 are, for example, disposed in the substrate 100, for isolating the memory cell columns 122. The isolation structures 102 are, for example, shallow trench isolation structures, and are made of silicon oxide.

The memory cell column 122 includes a plurality of memory units 124. Each of the memory units 124 comprises a word line 114, a composite layer 112, a doped region (source line) 108, a doped region (drain region) 110, a bit line 116, and a bit line 118. The word line 114 is, for example, disposed in the substrate 100, filling the corresponding trench 106 and extending in the trench 106, for connecting the memory units 124 in the same row. The material of the word line 114 is, for example, doped polysilicon.

The composite layer 112 is, for example, disposed between the word line 114 and the substrate 100. The composite layer 112 includes, for example, a dielectric layer 112a, a charge storage layer 112b, and a dielectric layer 112c, wherein the material of the dielectric layer 112a and the dielectric layer 112c is silicon oxide, and the material of the charge storage layer 112b is, for example, silicon nitride or doped polysilicon.

The doped region (source line) 108 is, for example, disposed in the substrate 100 under the corresponding trench 106, and shared by the memory units 124 in the same row. The doped region 108 is, for example, N-type doped region.

The doped regions (drain region) 110 are, for example, disposed in the substrate 100 on both sides of the trench 106, and are numbered along X direction in the same memory cell column 122 as (2n−1)th (e.g. the doped region 110-1 and 110-3 in FIG. 2) and 2nth (e.g. the doped region 110-2 in FIG. 2), wherein n is an integer larger than 1. A doped region 110 is shared by the adjacent two memory units 124. The doped region 110 is, for example, N-type doped region.

The bit line 116 and the bit line 118 are, for example, disposed on the substrate 100, and extend in X direction. The bit line 116 is electrically connected to the (2n−1)th doped region 110 (e.g. the doped region 110-1 and 110-3). The bit line 118 is electrically connected to the 2nth doped region 110 (e.g. the doped region 110-2). The material of the bit line 116 and the bit line 118 is, for example, the metal tungsten.

Moreover, the non-volatile memory array further comprises conductive plugs 120 disposed on the substrate 100 for connecting the (2n−1)th doped region 110 (e.g. the doped region 110-1 and 110-3) to the bit line 116, and the 2nth doped region 110 (e.g. the doped region 110-2) to the bit line 118 respectively. The material of the conductive plugs 120 is, for example, polysilicon.

In the above non-volatile memory array, each memory unit 124 can be divided into a first memory cell 124-1 and a second memory cell 124-2 disposed respectively on both sides of the word line 114. The first memory cell 124-1 and the second memory cell 124-2 share the word line 114, the doped region 108 and the composite layer 112. The adjacent two first memory cells 124-1 share a (2n−1)th doped region 110 (e.g. the doped region 110-1 or 110-3), and the adjacent two second memory cells 124-2 share a 2nth second doped regions 110 (e.g. the doped region 110-2), i.e., the memory cell connecting the doped region 110 to the bit line 116 is defined as the first memory cell 124-1, and the memory cell connecting the doped region 110 to the bit line 116 is defined as the second memory cell 124-2.

The above non-volatile memory structure has a vertical memory cell structure, and can store two bits per cell. Moreover, in the same memory cell column 122 of the non-volatile memory structure, due to the bit line 116 separated from the bit line 118, it is capable of performing programming/reading/erasing on two memory cells in the same memory unit.

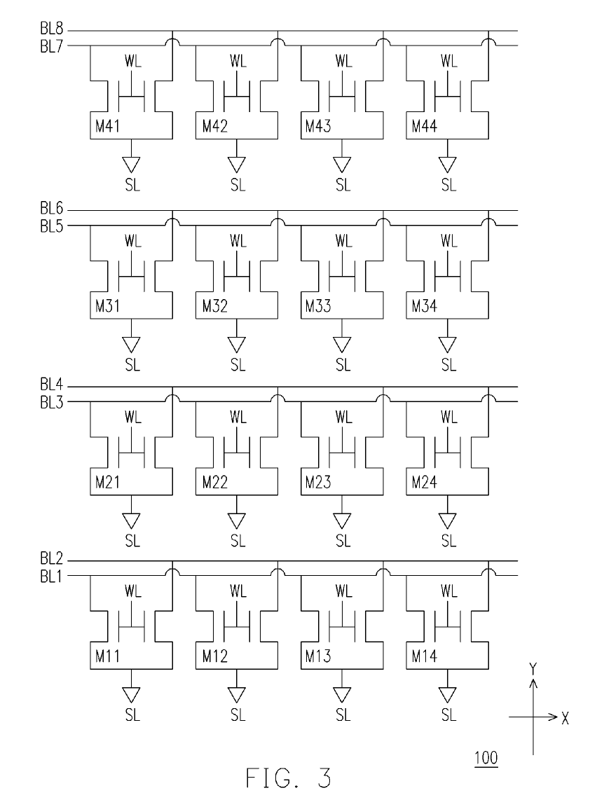

FIG. 3 shows a circuit diagram of the non-volatile memory according to an embodiment of the present invention.

Referring to FIG. 3, the non-volatile memory array of the present invention comprises word lines WL1˜WL4, source lines SL1˜SL4, bit lines BL1˜BL8 and memory units M11˜M44. The memory units M11˜M44 are arranged in array, wherein each of the M11˜M14, M21˜M24, M31˜M34, and M31˜M34 forms a memory cell column, and each of the M11˜M41, M12˜M42, M13˜M43, and M14˜M44 forms a memory cell row. The structure of each memory unit, for example, having a gate, a source region, two drain regions, and a charge storage layer, is shown in FIG. 2.

The word lines WL1˜WL4 extend in Y direction of a X-Y plane, wherein the Y direction is, for example, the row direction in the memory array, and the X direction is, for example, the column direction in the memory array. The word lines WL1˜WL4 are used for connecting the gates of memory units in the same memory cell row respectively. For example, the word line WL1 is used for connecting the gates of M11˜M41, and similarly, the word lines WL2, WL3, WL4 are used for connecting the gates of M12˜M42, M13˜M43, M14˜M44 respectively.

The source lines SL1˜SL4 extend along the Y direction, and are used for connecting the source regions of memory units in the same memory cell row respectively. For example, the source line SL1 is used for connecting the source regions of M11˜M41, and similarly, the source lines SL2, SL3, SL4 are used for connecting the source regions of M12˜M42, M13˜M43, M14˜M44 respectively.

The bit lines BL1˜BL8 extend along the X direction in a group of two bit lines, for example taking the bit line BL1 and BL2 as a group. In the same memory cell column, the drain regions are numbered along the column direction as (2n−1)th and 2nth, wherein n is an integer larger than 1. In the bit line group consisting of bit lines BL1 and BL2, bit line BL1 is connected to the (2n−1)th drain region in the memory cell column consisting of M11˜M14, while bit line BL2 is connected to the 2nth drain region in the memory cell column. And similarly, bit lines BL3 and BL4 form a bit line group, and bit lines BL5 and BL6 form a bit line group, and bit line BL7 and BL8 form a bit line group. The bit line groups are connected to (2n−1)th drain regions and 2nth drain regions in different columns of the memory cell columns respectively.

Next, the method of operating the non-volatile memory of the present invention is described by taking the memory units M11 and M12 in FIG. 3 as an example. In the operating method, the definition of the source line and the bit line is different depending on whether the bit to be operated is the upper bit or the bottom bit, so in the following description, the source lines SL1˜SL4 are commonly referred as conductive lines SL1˜SL4, and bit line BL1˜BL8 are commonly referred as conductive lines BL1˜BL8, for the purpose of clarification.

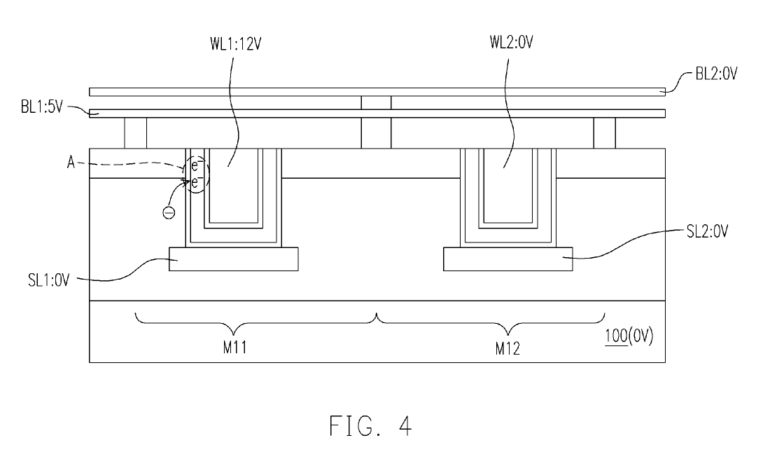

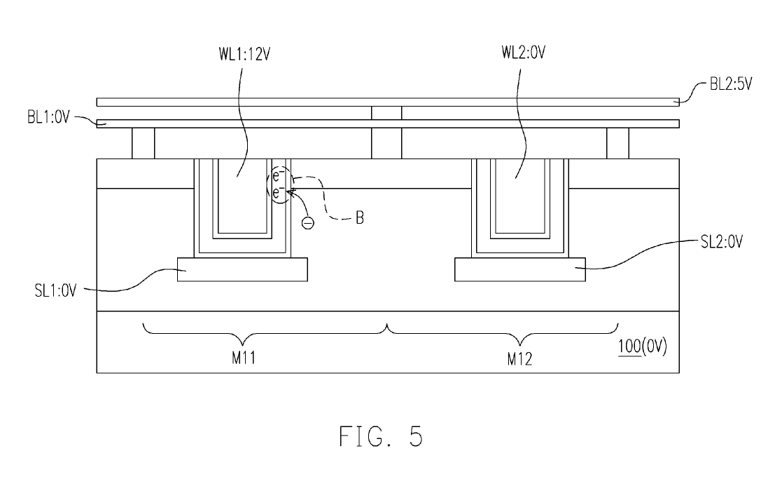

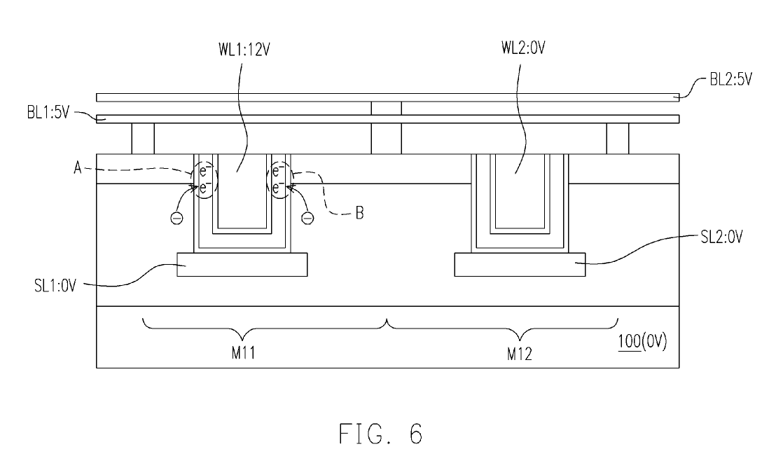

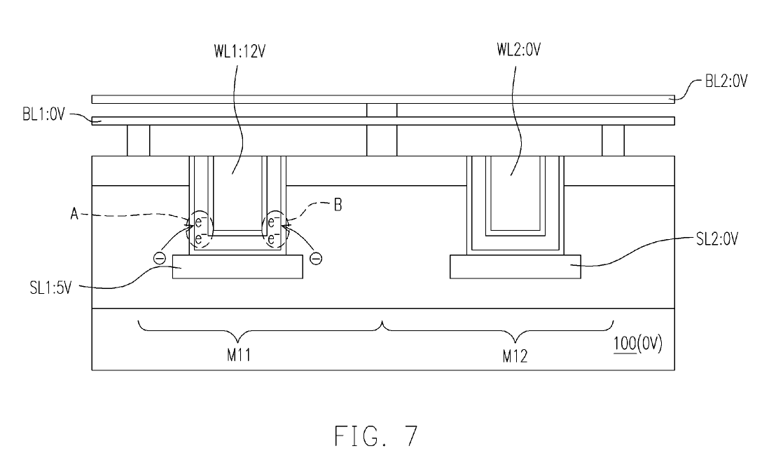

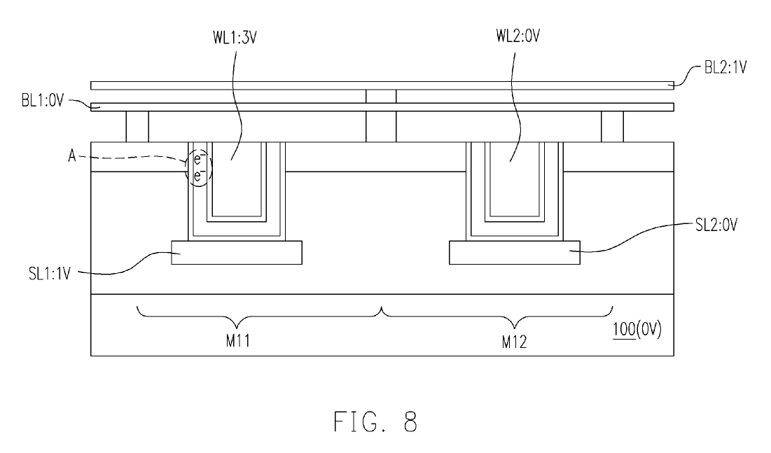

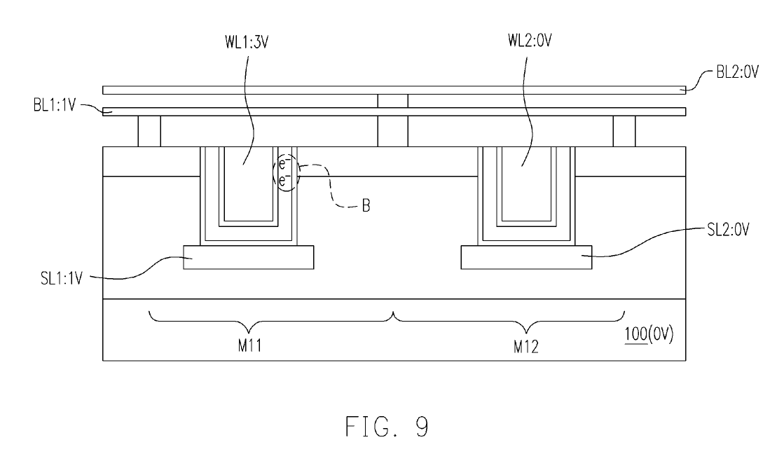

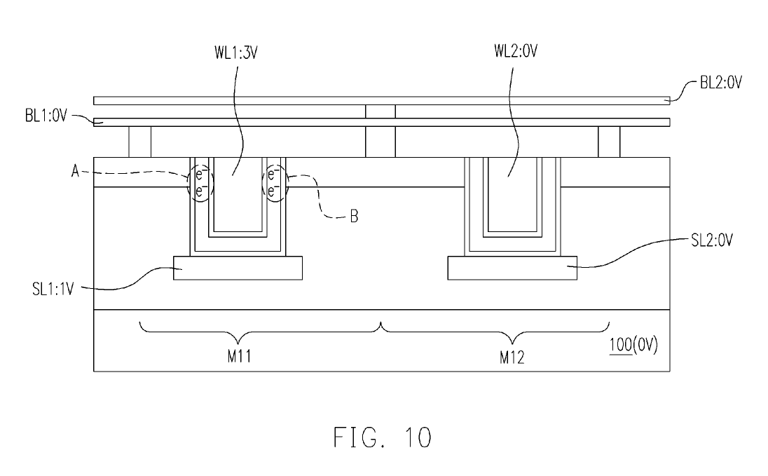

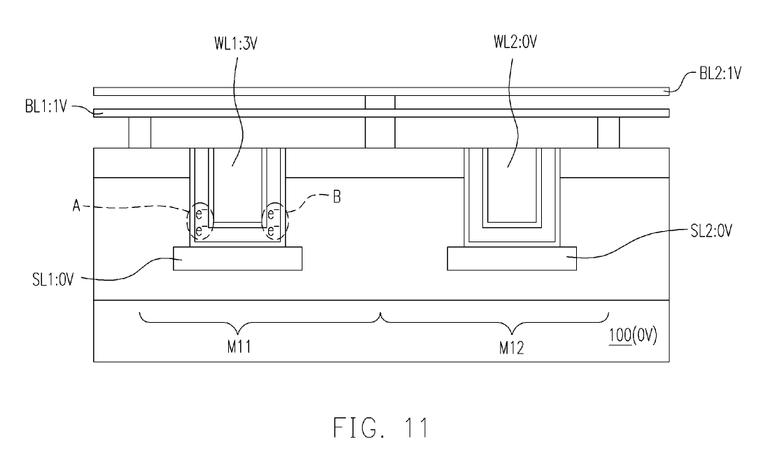

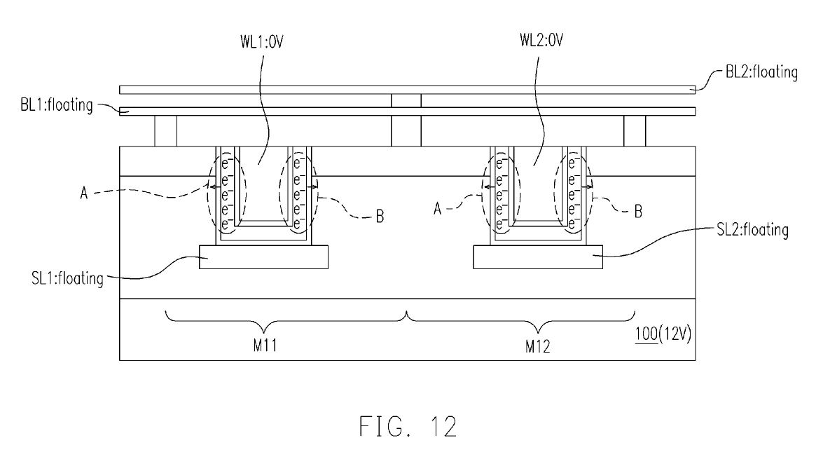

FIG. 4˜FIG. 7 are schematic views of the programming operation of an embodiment of the present invention. FIG. 8˜FIG. 11 are schematic views of the reading operation of an embodiment of the present invention. FIG. 12 is a schematic view of the erasing operation of an embodiment of the present invention. The non-volatile memory structure of FIG. 4˜FIG. 10 is described in details in FIG. 2 and FIG. 3, and will not be described herein.

Firstly, referring to FIG. 4, when programming an upper bit of the first memory cell A of selected memory unit M11, a first voltage, e.g. 5 volts, is applied to the corresponding conductive line BL1, and a second voltage, e.g. 0 volt, is applied to the conductive line SL1 of the selected first memory cell A, and a third voltage, e.g. 12 volts is applied to the word line WL1 of the selected first memory cell A, wherein the first voltage is higher than the second voltage for programming the upper bit of the selected first memory cell A, and the third voltage is higher than the threshold voltage of the first memory cell A. Meanwhile, a voltage of 0 volt can be applied to the substrate 100 and the word line WL2, the conductive line BL2 and the conductive line SL2 of other unselected memory unit M12.

Referring to FIG. 5, when programming an upper bit of the second memory cell B of the selected memory unit M11, a seventh voltage, e.g. 5 volts, is applied to the corresponding conductive line BL2, and an eighth voltage, e.g. 0 volt, is applied to the conductive line SL1 of the selected second memory cell B, and a ninth voltage, e.g. 12 volts, is applied to the word line WL1 of the selected second memory cell B, wherein the seventh voltage is higher than the eighth voltage for programming the upper bit of the selected second memory cell B, and the ninth voltage is higher than the threshold voltage of the first memory cell A. Meanwhile, a voltage of 0 volt can be applied to the substrate 100 and the word line WL2, the conductive line BL1, and the conductive line SL2 of other unselected memory unit M12.

Referring to FIG. 6, when programming the upper bits of the first memory cell A and the second memory cell B of the selected memory unit M11, a fifteenth voltage, e.g. 5 volts, is applied to the corresponding conductive lines BL1 and BL2, and a sixteenth voltage, e.g. 0 volt, is applied to the conductive line SL1 of the selected memory unit M11, and a seventeenth voltage, e.g. 12 volts, is applied to the word line WL1 of the selected memory unit M11, wherein the fifteenth voltage is higher than the sixteenth voltage for programming the selected first memory cell A and second memory cell B. Meanwhile, a voltage of 0 volt can be applied to the substrate 100 and the word line WL2 and the conductive line SL2 of other unselected memory unit M12.

Referring to FIG. 7, when programming the bottom bits of the first memory cell A and the second memory cell B of the selected memory unit M11, a sixteenth voltage, e.g. 0 volt, is applied to the corresponding conductive lines BL1 and BL2, and a fifteenth voltage, e.g. 5 volts, is applied to the conductive line SL1 of the selected memory unit M11, and a seventeenth voltage, e.g. 12 volts, is applied to the word line WL1 of the selected memory unit M11, for programming the bottom bits of the selected first memory cell A and second memory cell B. Meanwhile, a voltage of 0 volt can be applied to the substrate 100 and to the word line WL2 and the conductive line SL2 of other unselected memory unit M12.

Referring to FIG. 8, when reading an upper bit of the first memory cell A of the selected memory unit M11, a fourth voltage, e.g. 0 volt, is applied to the corresponding conductive line BL1 of the selected first memory cell A, and a fifth voltage, e.g. 1 volt, is applied to the conductive line SL1 of the selected first memory cell A, and a sixth voltage, e.g. 3 volts, is applied to the word line WL1 of the selected first memory cell A, wherein the fourth voltage is lower than the fifth voltage, and the sixth voltage is higher than the threshold voltage of the first memory cell A before it is programmed, and is lower than the threshold voltage of the first memory cell A after it is programmed, for reading the upper bit of the selected first memory cell A. Meanwhile, a voltage of 0 volt can be applied to the substrate 100 and the word line WL2 of other unselected memory unit M12, and a voltage of 1 volt can be applied to the conductive line BL2.

Referring to FIG. 9, when reading an upper bit of the second memory cell B of the selected memory unit M11, a tenth voltage, e.g. 0 volt, is applied to the corresponding conductive line BL2 of the selected second memory cell B, and a eleventh voltage, e.g. 1 volt, is applied to the conductive line SL1 of the selected second memory cell B, and a twelfth voltage, e.g. 3 volts, is applied to the word line WL1 of the selected second memory cell B, wherein the tenth voltage is lower than the eleventh voltage, and the twelfth voltage is higher than the threshold voltage of the second memory cell B before it is programmed, and is lower than the threshold voltage of the second memory cell B after it is programmed, for reading the upper bit of the selected second memory cell B. Meanwhile, a voltage of 0 volt can be applied to the substrate 100 and the word line WL2 of other unselected memory unit M12, and a voltage of 1 volt can be applied to the conductive line BL2.

Referring to FIG. 10, when reading the upper bits of the first memory cell A and the second memory cell B of the selected memory unit M11, an eighteenth voltage, e.g. 0 volt, is applied to the corresponding conductive lines BL1 and BL2, and a nineteenth voltage, e.g. 1 volt, is applied to the conductive line SL1 of the selected memory unit M11, and a twentieth voltage, e.g. 3 volts, is applied to the word line WL1 of the selected memory unit M11, wherein the eighteenth voltage is lower than the nineteenth voltage for reading the upper bits of the selected first memory cell A and the selected second memory cell B. Meanwhile, a voltage of 0 volt can be applied to the substrate 100 and the word line WL2 of other unselected memory unit M12.

Referring to FIG. 11, when reading the bottom bits of the first memory cell A and the second memory cell B of the selected memory unit M11, a nineteenth voltage, e.g. 1 volt, is applied to the corresponding conductive lines BL1 and BL2, and a eighteenth voltage, e.g. 1 volt, is applied to the conductive line SL1 of the selected memory unit M11, and a twentieth voltage, e.g. 3 volts, is applied to the word line WL1 of the selected memory unit M11, for reading the bottom bits of the selected first memory cell A and the selected second memory cell B. Meanwhile, a voltage of 0 volt can be applied to the substrate 100 and to the word line WL2 of other unselected memory unit M12.

Referring to FIG. 12, when erasing the above non-volatile memory, a thirteenth voltage, e.g. 12 volts, is applied to the substrate 100, and a fourteenth voltage, e.g. 0 volt, is applied to the word lines WL1 and WL2 of the selected memory units M11 and M12, wherein the thirteenth voltage is higher than the fourteenth voltage, for erasing the first memory cell A and the second memory cell B of the memory units M11 and M12 by the F-N tunneling effect. Meanwhile, the conductive line SL1, the conductive line BL1, and the conductive line BL2 are floated, i.e. no voltage is applied to them.

The above method of operating the non-volatile memory provided in the present invention can be used to perform operations on a memory cell of a selected memory unit, and also perform operations on two memory cells of a memory unit at the same time. Besides, the method of operating the non-volatile memory provided in the present invention can be further used to perform operations on the selected memory cells in multiple selected memory units at the same time. Thus, it is much easier to perform operations on the memory unit according to the requirements of the operation.

In view of the above, the present invention at least has the following advantages.

1. The non-volatile memory structure of the present invention allows performing programming/reading/easing on two memory cells in the same memory unit because of the separated bit lines.

2. In the method of manufacturing the non-volatile memory of the present invention, the word lines, source line and drain region can be formed in a self-aligned way, thus simplifying the process efficiently, and reducing the production cycle.

3. According to the method of operating the non-volatile memory of the present invention, it is much easier to perform operations on the memory unit(s) according to the requirements of the operation by using the separated bit lines.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A non-volatile memory unit, comprising:
a substrate having a trench extending in a first direction;
a conductive layer disposed in the trench;
a charge storage layer disposed between the conductive layer and the substrate;
a first doped region disposed in the substrate under the trench;
two second doped regions, each disposed in the substrate at one side of the trench respectively; and
a first conductive line and a second conductive line disposed on the substrate and parallel to each other, and electrically connected to the two second doped regions respectively, and the first conductive line and the second conductive line extending in a second direction that is perpendicular to the first direction of the conductive layer.

2. The non-volatile memory unit as claimed in claim 1, further comprising a plurality of conductive plugs disposed on the substrate, for connecting the second doped region at one side of the trench to the first conductive line, and the second doped region at the other side of the trench to the second conductive line respectively.

3. The non-volatile memory unit as claimed in claim 1, wherein a material of the conductive layer is doped polysilicon.

4. The non-volatile memory unit as claimed in claim 1, wherein a material of the charge storage layer comprises silicon nitride.

5. The non-volatile memory unit as claimed in claim 1, further comprising a first dielectric layer disposed under the charge storage layer.

6. The non-volatile memory unit as claimed in claim 5, wherein a material of the first dielectric layer comprises silicon oxide.

7. The non-volatile memory unit as claimed in claim 1, further comprising a second dielectric layer disposed between the charge storage layer and the conductive layer.

8. The non-volatile memory unit as claimed in claim 7, wherein a material of the second dielectric layer comprises silicon oxide.

9. The non-volatile memory unit as claimed in claim 1, wherein a material of the conductive plugs comprises polysilicon.

10. The non-volatile memory unit as claimed in claim 1, wherein a material of the first conductive line and the second conductive line comprises tungsten.

11. A non-volatile memory array, comprising:
a substrate with a plurality of trenches, the trenches being parallel to each other and extending in row direction;
a plurality of memory cell units constituting a plurality of memory cell columns, wherein each of the memory cell units comprises:
a word line disposed in one of the trenches, and extending along the trench, wherein the memory units in a same row share a common word line;
a charge storage layer disposed between the word line and the trench;
a first doped region disposed in the substrate under the trench, and shared by the memory units in the same row; and
a second doped region and a third doped region, each disposed in the substrate at one side of the trench respectively;
a first conductive line and a second conductive line disposed on the substrate in parallel, extending in column direction, and electrically connected to the second doped region and the third doped region respectively;
a third conductive line disposed on the substrate, connecting to the first doped region; and
a plurality of isolation structures disposed in the substrate, for isolating the memory cell columns, wherein
the second doped regions and the third doped regions of the memory cell units in a same column are arranged alternatively, and every two adjacent memory cell units share one of the second doped regions or the third doped regions.

12. The non-volatile memory array as claimed in claim 11, further comprising a plurality of conductive plugs disposed on the substrate, for connecting the second doped region to the first conductive line, the third doped region to the second conductive line, and the first doped region to the third conductive line respectively.

13. The non-volatile memory array as claimed in claim 11, wherein the isolation structures comprise shallow trench isolation structures.

14. The non-volatile memory array as claimed in claim 11, wherein a material of the word line is doped polysilicon.

15. The non-volatile memory array as claimed in claim 11, wherein a material of the charge storage layer comprises silicon nitride.

16. The non-volatile memory array as claimed in claim 11, further comprising a plurality of first dielectric layers, each being disposed between the charge storage layer and a surface of the trench.

17. The non-volatile memory array as claimed in claim 16, wherein a material of the first dielectric layer comprises silicon oxide.

18. The non-volatile memory array as claimed in claim 11, further comprising a plurality of second dielectric layers disposed between the charge storage layers and the word lines respectively.

19. The non-volatile memory array as claimed in claim 18, wherein a material of the second dielectric layers comprises silicon oxide.

20. The non-volatile memory array as claimed in claim 11, wherein a material of the conductive plugs comprises polysilicon.

21. The non-volatile memory array as claimed in claim 11, wherein a material of the first conductive line and the second conductive line comprises tungsten.

22. A method of manufacturing a non-volatile memory, comprising:
providing a substrate;
forming a plurality of isolation structures in the substrate, the isolation structures being arranged in parallel and extending in a first direction;
forming a plurality of trenches in the substrate, the trenches being arranged in parallel and extending in a second direction perpendicular to the first direction;
forming a plurality of first doped regions in the substrates under the trenches;
forming a plurality of second doped regions and a plurality of third doped regions in the substrate at both sides of the trenches, the second doped regions and the third doped regions being arranged alternatively in the first direction;
forming a plurality of charge storage layers on surfaces of the trenches;
forming a plurality of word lines to fill up the trenches; and
forming a plurality of first conductive lines and a plurality of second conductive lines on the substrate, wherein the first conductive lines and the second conductive lines are electrically connected to the second doped regions and the third doped regions respectively, and are arranged in parallel and extend in the first direction.

23. The method as claimed in claim 22, further comprising forming a plurality of conductive plugs on the substrate, for respectively connecting the second doped regions to the first conductive lines, and the third doped regions to the second conductive lines.

24. The method as claimed in claim 22, wherein the method for forming the first doped regions, the second doped regions and the third doped regions comprises ion implantation.

25. The method as claimed in claim 22, wherein a material of the charge storage layers comprises silicon nitride.

26. The method as claimed in claim 22, further comprising forming a first dielectric layer between the charge storage layer and the substrate.

27. The method as claimed in claim 26, wherein a material of the first dielectric layers comprises silicon oxide.

28. The method as claimed in claim 22, further comprising forming a second dielectric layer between the charge storage layer and the word line.

29. The method as claimed in claim 28, wherein a material of the second dielectric layers comprises silicon oxide.

30. The method as claimed in claim 22, wherein the method for forming the word lines comprises:
forming a conductive material layer over the substrate to fill the trenches; and removing the conductive material layer outside the trenches.

31. The method as claimed in claim 22, wherein the method for removing the conductive material layer outside the trenches comprises chemical mechanical polishing.

32. A method of operating a non-volatile memory, suitable for a memory cell array arranged in columns/rows, the memory cell array comprising a plurality of memory units, wherein each of the memory units comprises a word line disposed in a trench of a substrate and extending in the trench, for connecting the memory units in the same row; a charge storage layer disposed between the word line and the substrate; a first doped region disposed in the substrate under the trench, and shared by the memory units in the same row; a second doped region and a third doped region, disposed in the substrate at both sides of the trench respectively; and a first conductive line and a second conductive line, disposed on the substrate, extending along the column direction, and electrically connected to the second doped region and the third doped region respectively, wherein each of the second doped region or the third doped region is shared by two adjacent memory units, and the structure of each of the memory units constitutes a first memory cell and a second memory cell at both sides of each word line, and the method of operating non-volatile memory comprising:
when programming, applying a first voltage to the first conductive line corresponding to a first memory cell of a selected memory unit, a second voltage to the first doped region of the selected first memory cell, and a third voltage to the word line of the selected first memory cell, wherein the first voltage is higher than the second voltage, and the third voltage is higher than a threshold voltage of the selected memory unit for programming an upper bit of the first memory cell; and
applying the second voltage to the first conductive line corresponding to the selected first memory cell, and the first voltage to the first doped region of the selected first memory cell, and the third voltage to the word line of the selected first memory cell, for programming a bottom bit of the first memory cell.

33. The method as claimed in claim 32, comprising: when programming, applying a seventh voltage to the second conductive line corresponding to a second memory cell of the selected memory unit, an eighth voltage to the first doped region of the selected second memory cell, and a ninth voltage to the word line of the selected second memory cell, wherein the seventh voltage is higher than the eighth voltage, and the ninth voltage is higher than the threshold voltage of the selected memory unit for programming an upper bit of the selected second memory cell; and
applying the eighth voltage to the second conductive line corresponding to the selected second memory cell, the seventh voltage to the first doped region of the selected second memory cell, and the ninth voltage to the word line of the selected second memory cell, for programming a bottom bit of the selected second memory cell.

34. The method as claimed in claim 33, comprising:
when reading the upper bit of the selected second memory cell, applying a tenth voltage to the second conductive line corresponding to the selected second memory cell, an eleventh voltage to the first doped region of the selected second memory cell, and a twelfth voltage to the word line of the selected second memory cell, wherein the tenth voltage is lower than the eleventh voltage, the twelfth voltage is higher than a threshold voltage of the second memory cell before it is programmed, and is lower than a threshold voltage of the second memory cell after it is programmed; and
when reading the bottom bit of the second memory cell, applying the eleventh voltage to the second conductive line corresponding to the selected second memory cell, the tenth voltage to the first doped region of the selected second memory cell, and the twelfth voltage to the word line of the selected second memory cell.

35. The method as claimed in claim 32, comprising:
when reading the upper bit of the selected first memory cell, applying a fourth voltage to the first conductive line corresponding to the selected first memory cell, a fifth voltage to the first doped region of the selected first memory cell, and a sixth voltage to the word line of the selected first memory cell, wherein the fourth voltage is lower than the fifth voltage, and the sixth voltage is higher than a threshold voltage of the first memory cell before it is programmed, and is lower than a threshold voltage of the first memory cell after it is programmed; and
when reading the bottom bit of the selected first memory cell, applying the fifth voltage to the first conductive line corresponding to the selected first memory cell, the fourth voltage to the first doped region of the selected first memory cell, and the sixth voltage to the word line of the selected first memory cell.

36. The method as claimed in claim 32, comprising applying a thirteenth voltage to the substrate and applying a fourteenth voltage to the word line of the selected memory unit when erasing, wherein the thirteenth voltage is higher than the fourteenth voltage, for erasing by F-N tunneling effect.
